(19) United States
(12) Patent Application Publication
(10) Pub. No.: US 2026/0007044 A1
(43) Pub. Date: Jan. 1, 2026

(54) DISPLAY APPARATUS AND ELECTRONIC APPARATUS INCLUDING THE DISPLAY APPARATUS

(71) Applicants: Samsung Display Co., Ltd., Yongin-si (KR); Foundation of Soongsil University-Industry Cooperation, Seoul (KR)

(72) Inventors: Seungho Kim, Yongin-si (KR); Junhyup Lee, Seoul (KR); Kangwoo Lee, Yongin-si (KR); Intae Son, Yongin-si (KR); Dohyun Kim, Seoul (KR); Jinwook Kim, Seoul (KR)

(21) Appl. No.: 19/252,436

(22) Filed: Jun. 27, 2025

(30) Foreign Application Priority Data
Jun. 27, 2024 (KR) 10-2024-0084820

(51) Int. Cl. H10K 59/80; H10K 102/00

(52) U.S. Cl. CPC H10K 59/8722; H10K 2102/331

(57) ABSTRACT

Provided is a display apparatus including a display panel, an optically clear adhesive (OCA) over the display panel, and an auxiliary layer between the display panel and the OCA and including a nanocapsule and an OCA composition, wherein the nanocapsule is a gas-generating particle and has a diameter of at least about 100 nm and not more than about 2 μm.

### CROSS-REFERENCE TO RELATED APPLICATION

The present application claims priority to and the benefit of Korean Patent Application No. 10-2024-0084820, filed on Jun. 27, 2024, in the Korean Intellectual Property Office, the entire content of which is hereby incorporated by reference.

### BACKGROUND

### 1. Field

One or more embodiments relate to a display apparatus and electronic apparatus including the display apparatus.

### 2. Description of the Related Art

Display apparatuses visually display data. Display apparatuses may provide images by using light-emitting diodes. Applications of display apparatuses have diversified, and various designs for improving the quality of display apparatuses have been attempted.

### SUMMARY

One or more embodiments include a display apparatus and electronic apparatus including the display apparatus.

Additional aspects of embodiments of the present disclosure will be set forth in part in the description which follows and, in part, will be apparent from the description, or may be learned by practice of the presented embodiments of the disclosure.

According to one or more embodiments, a display apparatus includes a display panel, an optically clear adhesive (OCA) over the display panel, and an auxiliary layer between the display panel and the OCA and including a nanocapsule and an OCA composition, wherein the nanocapsule is a gas-generating particle and has a diameter of at least about 100 nm and not more than about 2 μm.

According to embodiments, the auxiliary layer may be in contact with an interface of the display panel.

According to embodiments, a core of the nanocapsule may include an inorganic material.

According to embodiments, the core of the nanocapsule may include an inorganic material that generates gas by thermal decomposition at a temperature of at least about 50° C. and not more than about 100° C.

According to embodiments, the core of the nanocapsule may include sodium bicarbonate (NaHCO₃).

According to embodiments, the core of the nanocapsule may include at least one of zinc hydroxide (Zn(OH)₂), ammonium bicarbonate (NH₄HCO₃), aluminum hydroxide (Al(OH)₃), calcium carbonate (CaCO₃), hydrogen sulfide (H₂S), sulfur dioxide (SO₂), nitric oxide (NO), nitrous oxide (N₂O), or arsenic trioxide (As₂O₃).

According to embodiments, a shell of the nanocapsule may include an acrylic monomer.

According to embodiments, the shell of the nanocapsule may include polyacrylonitrile (PAN) and polymethyl methacrylate (PMMA).

According to embodiments, a ratio of PAN and PMMA, included in the shell of the nanocapsule may be between about 0:10 and about 9:1.

According to embodiments, the shell of the nanocapsule may include at least one of methyl methacrylate, acrylonitrile, 2-ethylhexyl acrylate, N-butyl acrylate, vinyl acetate, ethyl acrylate, methyl acrylate, benzyl acrylate, phenoxyethyl acrylate, acrylic acid, hydroxyethyl methacrylate, glycidyl methacrylate, acetoacetoxyethyl methacrylate, 2-hydroxyethyl acrylate, isobornyl acrylate, or octadecyl methacrylate.

According to embodiments, the OCA composition may include at least one of 2-ethylhexyl acrylate, N-butyl acrylate, vinyl acetate, methyl methacrylate, ethyl acrylate, methyl acrylate, benzyl acrylate, phenoxyethyl acrylate, acrylic acid, hydroxyethyl methacrylate, glycidyl methacrylate, acetoacetoxyethyl methacrylate, 2-hydroxyethyl acrylate, or isobornyl acrylate.

According to one or more embodiments, a display apparatus includes a display panel, an optically clear adhesive (OCA) on the display panel, an auxiliary layer on the OCA and including a nanocapsule and an OCA composition, and a member on the auxiliary layer, wherein the nanocapsule is a gas-generating particle and has a diameter of at least about 100 nm and not more than about 2 μm.

According to embodiments, the auxiliary layer may be in contact with an interface of the member.

According to embodiments, a core of the nanocapsule may include an inorganic material.

According to embodiments, the core of the nanocapsule may include an inorganic material that generates gas by thermal decomposition at a temperature of at least about 50° C. and not more than about 100° C.

According to embodiments, the core of the nanocapsule may include sodium bicarbonate (NaHCO₃).

According to embodiments, the core of the nanocapsule may include at least one of zinc hydroxide (Zn(OH)₂), ammonium bicarbonate (NH₄HCO₃), aluminum hydroxide (Al(OH)₃), calcium carbonate (CaCO₃), hydrogen sulfide (H₂S), sulfur dioxide (SO₂), nitric oxide (NO), nitrous oxide (N₂O), or arsenic trioxide (As₂O₃).

According to embodiments, a shell of the nanocapsule may include an acrylic monomer.

According to embodiments, the shell of the nanocapsule may include polyacrylonitrile (PAN) and polymethyl methacrylate (PMMA).

According to embodiments, a ratio of PAN and PMMA, included in the shell of the nanocapsule may be between about 0:10 and about 9:1.

According to embodiments, an electronic apparatus includes a display apparatus including a display panel; an optically clear adhesive (OCA) over the display panel; and an auxiliary layer between the display panel and the OCA and comprising a nanocapsule and an OCA composition, wherein the nanocapsule is a gas-generating particle and has a diameter of at least about 100 nm and not more than about 2 μm.

The electronic apparatus may include a mobile phone, a smartphone, a tablet personal computer (PC), a mobile communication terminal, an electronic organizer, an e-book, a portable multimedia player (PMP), a navigation device, an ultra mobile PC (UMPC), a television, a laptop, a monitor, a billboard, an Internet of things (IOT) device, a wearable device, or a vehicle.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a perspective view schematically showing a display apparatus according to an embodiment;

FIG. 2 is a cross-sectional view schematically showing a cross-section of the display apparatus of FIG. 1 taken along a line A-A′ of FIG. 1;

FIG. 3 is a plan view schematically showing a display panel included in a display apparatus according to an embodiment;

FIG. 4 is an equivalent circuit diagram schematically showing a pixel circuit of a display panel and a display element connected to the pixel circuit;

FIG. 5 is a cross-sectional view schematically showing a cross-section of the display panel of FIG. 3 taken along a line B-B′ of FIG. 3;

FIG. 6 schematically shows a cross-section of a display panel according to an embodiment and a member that are bonded to each other via an optically clear adhesive (OCA) and an auxiliary layer;

FIG. 7 schematically shows a perspective view of a nanocapsule included in an auxiliary layer;

FIG. 8 schematically shows an enlarged view of a region A of a cross-section of the display apparatus shown in FIG. 6;

FIGS. 9-10 schematically show an embodiment of a method of preparing a material for forming an auxiliary layer;

FIG. 11 schematically shows a result of measuring initial adhesions and debonding adhesions of samples of materials for forming an auxiliary layer according to an embodiment; and

FIG. 12 schematically shows light transmittances of samples of materials for forming an auxiliary layer according to an embodiment.

### DETAILED DESCRIPTION

Reference will now be made in more detail to embodiments, examples of which are illustrated in the accompanying drawings, wherein like reference numerals refer to like elements throughout the present specification. In this regard, the present embodiments may have different forms and should not be construed as being limited to the descriptions set forth herein. Accordingly, the embodiments are merely described below, by referring to the drawings, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various suitable modifications may be applied to the present embodiments, and example embodiments will be illustrated in the drawings and described in the detailed description section. The effect and features of embodiments of the disclosure, and a method to achieve the same, will be clearer referring to the detailed descriptions below with the drawings. However, the present embodiments may be implemented in various suitable forms, and are not limited to the embodiments presented below.

Hereinafter, embodiments of the present disclosure will be described in more detail with reference to the accompanying drawings, and in the description with reference to the drawings, the same or corresponding components are indicated by the same reference numerals and redundant descriptions thereof may not be repeated.

In the following embodiment, it will be understood that although the terms “first,” “second,” etc. may be used herein to describe various components, these components should not be limited by these terms. These terms are only used to distinguish one component from another.

In the following embodiment, the expression of singularity in the present specification includes the expression of plurality unless clearly specified otherwise in context.

In the following embodiments, it will be further understood that the terms “comprises” and/or “comprising” used herein specify the presence of stated features or components, but do not preclude the presence or addition of one or more other features or components.

In the following embodiment, it will be understood that when a layer, region, or component is referred to as being “on” or “formed on” another layer, region, or component, it can be directly or indirectly on or formed on the other layer, region, or component. For example, intervening layers, regions, or components may be present.

Sizes of components in the drawings may be exaggerated for convenience of explanation. Because sizes and thicknesses of components in the drawings may be arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the present specification, the expression “A and/or B” represents A, B, or A and B. In embodiments, the expression “at least one of A and B” represents A, B, or A and B.

It will be understood that when a layer, region, or component is referred to as being “connected to” another layer, area, or component, it can be directly or indirectly connected to the other layer, region, or component. For example, intervening layers, regions, or components may be present. For example, in the present specification, when a layer, region, or component is electrically connected to another layer, region, or component, the layers, regions, or components may not only be directly electrically connected, but may also be indirectly electrically connected via another layer, region, or component therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

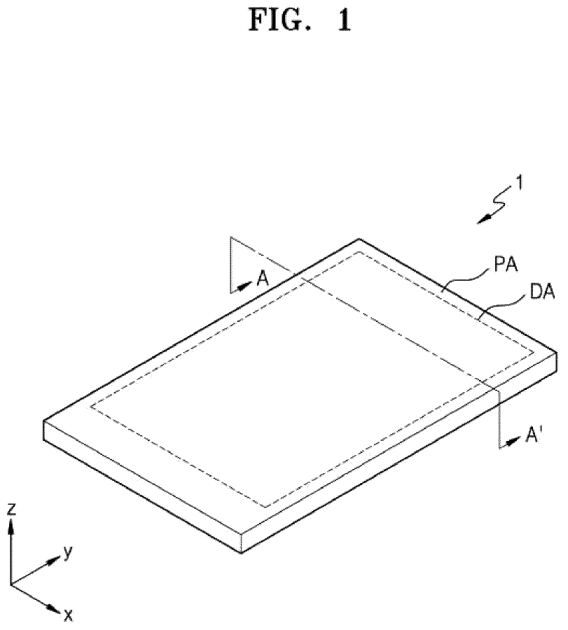

FIG. 1 is a perspective view schematically showing a display apparatus 1 according to an embodiment.

The display apparatus 1 displays moving images or still images, and may be a portable electronic apparatus, such as a mobile phone, a smartphone, a tablet personal computer (PC), a mobile communication terminal, an electronic organizer, an e-book, a portable multimedia player (PMP), a navigation device, or an ultra mobile PC (UMPC). The display apparatus 1 may be an electronic apparatus, such as a television, a laptop, a monitor, a billboard, or an Internet of things (IOT) device. In embodiments, the display apparatus 1 may be a wearable device, such as a smart watch, a watch phone, a glasses-type display, or a head-mounted display (HMD). In embodiments, the display apparatus 1 may be a part of another apparatus. For example, the display apparatus 1 may be a display portion of any suitable electronic apparatus. In embodiments, the display apparatus 1 may be an instrument panel of vehicles, a center information display (CID) on a center fascia or dashboard of a vehicle, a room mirror display in place of or in addition to side-view mirrors of a vehicles, or a display portion provided at a rear side of a front seat as an entertainment device for a rear seat of the vehicle.

As shown in FIG. 1, the display apparatus 1 may include a display region DA and a peripheral region PA surrounding the display region DA. The display apparatus 1 may provide an image via an array of a plurality of pixels two-dimensionally provided in the display region DA. Each of the plurality of pixels of the display apparatus 1 is a region capable of emitting light of a set or certain color, and the display apparatus 1 may provide an image by using the light emitted from the pixels. For example, each of the plurality of pixels may emit red light, green light, or blue light.

The display region DA may have a polygonal shape including a quadrangle as shown in FIG. 1. For example, the display region DA may have a rectangular shape in which a horizontal length is less than a vertical length, or a rectangular shape in which a horizontal length is greater than a vertical length, or may have a square shape. In embodiments, the display region DA may have various suitable shapes such as an ellipse or a circle.

The peripheral region PA is a non-display region that does not provide an image, and may entirely surround the display region DA. A driver or a main power line, configured to provide an electrical signal or power to pixel circuits, may be provided in the peripheral region PA. A pad that is a region to which an electronic device or a printed circuit board may be electrically connected may be provided in the peripheral region PA.

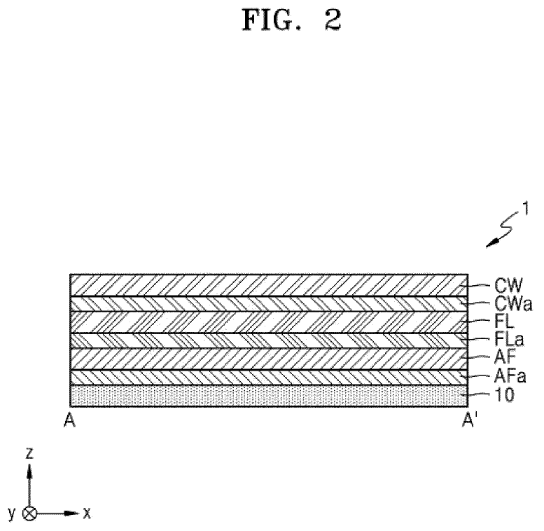

FIG. 2 is a cross-sectional view schematically showing a cross-section of the display apparatus 1 of FIG. 1 taken along a line A-A′ of FIG. 1. As shown in FIG. 2, the display apparatus 1 may include a display panel 10, an antenna film AF, a functional layer FL, and a cover window CW. The display apparatus 1 may further include an antenna film adhesive layer AFa, a functional layer adhesive layer FLa, and a cover window adhesive layer CWa.

The display panel 10 may display an image. In embodiments, the image provided by the display apparatus 1 may be understood as being implemented by the display panel 10. The display panel 10 may include a plurality of display elements, and the plurality of display elements may emit light. Therefore, the display panel 10 may display an image via the light emitted from the plurality of display elements.

In an embodiment, a display element may be an organic light-emitting diode including an organic emission layer. In embodiments, the display element may be a light-emitting diode (LED). The size of the LED may be micro scale or nano scale. For example, the LED may be a micro LED. In embodiments, the LED may be a nanorod LED. The nanorod LED may include gallium nitride (GaN). In an embodiment, a color conversion layer may be on the nanorod LED. The color conversion layer may include quantum dots. In embodiments, the display element may be a quantum dot LED including a quantum dot emission layer. In embodiments, the display element may be an inorganic light-emitting diode including an inorganic semiconductor.

The cover window CW may be above the display panel 10. In more detail, the cover window CW may be on a top surface of the display panel 10 (in a +z direction). In embodiments, the “top surface” of the display panel 10 may be defined as a surface facing a direction in which the display panel 10 provides an image. According to an embodiment, the cover window CW may cover the top surface of the display panel 10. The cover window CW may protect the top surface of the display panel 10. In embodiments, the cover window CW forms the exterior of the display apparatus 1, and thus may include flat and curved surfaces corresponding to a shape of the display apparatus 1.

The cover window CW may have a high transmittance to transmit light emitted from the display panel 10 and may be thin to minimize or reduce a weight of the display apparatus 1. In embodiments, the cover window CW may have high strength and hardness to protect the display panel 10 from external shock. The cover window CW may be a flexible window. The cover window CW may protect the display panel 10 by easily bending in response to external forces without causing cracks, and/or the like.

The cover window CW may include glass, sapphire, and/or plastic. For example, the cover window CW may be ultra-thin glass (UTG@) of which strength has been strengthened by chemical and/or thermal strengthening, and/or may be colorless polyimide (CPI). The cover window CW may have a structure in which a flexible polymer layer is on one surface of a glass substrate, or may only include a polymer layer. An image displayed by the display panel 10 may be provided to a user via the transparent cover window CW. In embodiments, the image provided by the display apparatus 1 may be understood as being implemented by the display panel 10.

The antenna film AF may be disposed between the display panel 10 and the cover window CW. In detail, the antenna film AF may be disposed above the display panel 10, and the cover window CW may be above the antenna film AF. The antenna film AF may transmit, receive, or transceive a wireless communication signal, for example, a wireless frequency signal. The antenna film AF may include a plurality of antennas, a plurality of antenna lines, and a plurality of antenna pads. Each of the plurality of antennas may transmit, receive, or transceive a same frequency band, or may transmit, receive, or transceive different frequency bands. The plurality of antennas, the plurality of antenna lines, and the plurality of antenna pads are further described herein.

In an embodiment, the functional layer FL may be between the antenna film AF and the cover window CW. Accordingly, the functional layer FL may be above the antenna film AF, and the cover window CW may be above the functional layer FL.

In an embodiment, the functional layer FL may be an optical functional layer that reduces reflectance of light (for example, external light) incident on the display panel 10 from the outside. Accordingly, the functional layer FL may improve color purity of light emitted from the display panel 10. The functional layer FL may include a polarizing film including a retarder and a polarizer. The retarder may include a λ/2 retarder and/or a λ/4 retarder.

In another embodiment, the functional layer FL may be a protective layer that protects the display panel 10 from external shock. Accordingly, the functional layer FL may include polymer resin. For example, the functional layer FL may include at least one of polyethersulfone, polyacrylate, polyetherimide, polyethylene naphthalate, polyethylene terephthalate, polyphenylene sulfide, polyimide, polycarbonate, or cellulose acetate propionate. In embodiments, the functional layer FL may include a material such as glass and/or quartz.

In embodiments, each of the adhesive layers may be between components of the display apparatus 1, and thus may attach one component of the display apparatus 1 to another component. In more detail, the antenna film adhesive layer AFa may be between the display panel 10 and the antenna film AF. The antenna film adhesive layer AFa may attach the antenna film AF to the display panel 10. The functional layer adhesive layer FLa may be between the antenna film AF and the functional layer FL. The functional layer adhesive layer FLa may attach the functional layer FL to the antenna film AF. The cover window adhesive layer CWa may be between the functional layer FL and the cover window CW. The cover window adhesive layer CWa may attach the cover window CW to the functional layer FL.

The antenna film adhesive layer AFa, the functional layer adhesive layer FLa, and the cover window adhesive layer CWa may each be, for example, an optically clear adhesive (OCA). In an embodiment, the functional layer adhesive layer FLa and the cover window adhesive layer CWa may include the same material as the antenna film adhesive layer AFa. In another embodiment, the functional layer adhesive layer FLa and the cover window adhesive layer CWa may include a different material from the antenna film adhesive layer AFa.

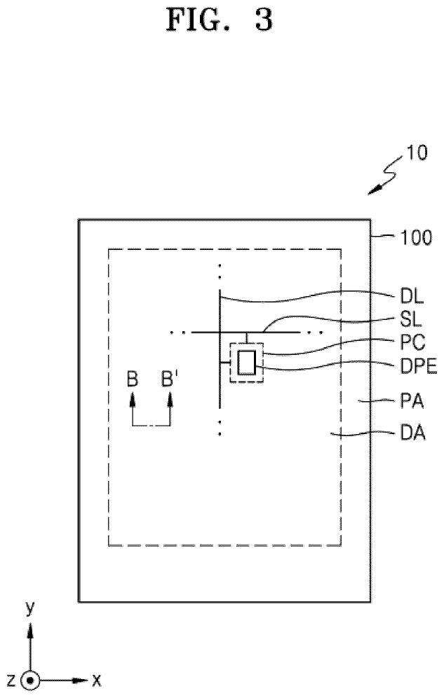

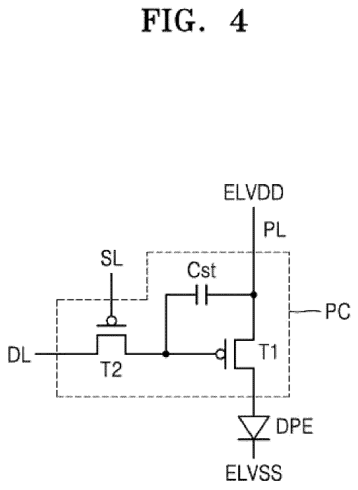

FIG. 3 is a plan view schematically showing the display panel 10 included in the display apparatus 1 according to an embodiment. FIG. 4 is an equivalent circuit diagram schematically showing a pixel circuit PC of the display panel 10 and a display element DPE connected to the pixel circuit PC. One display element DPE may correspond to one pixel, and the display element DPE may be an organic light-emitting diode.

The display panel 10 may include a substrate 100, the pixel circuit PC, a scan line SL, a data line DL, a driving voltage line PL, and the display element DPE. As described above, the display apparatus 1 includes the display panel 10, and the display panel 10 includes the substrate 100. In embodiments, because the display apparatus 1 includes the substrate 100, the substrate 100 has the display region DA and the peripheral region PA. Hereinafter, for convenience, it is described that the substrate 100 has the display region DA and the peripheral region PA.

The pixel circuit PC and the display element DPE may be provided in the display region DA. The pixel circuit PC may include a driving transistor T1, a switching transistor T2, and a storage capacitor Cst. The display element DPE may emit red light, green light, or blue light, or may emit red light, green light, blue light, or white light.

The switching transistor T2 is connected to the scan line SL and the data line DL, and may be configured to transmit, to the driving transistor T1, a data voltage or a data signal, input from the data line DL, according to a scan voltage or a scan signal, input from the scan line SL.

The storage capacitor Cst is connected to the switching transistor T2 and the driving voltage line PL, and may store a voltage corresponding to a difference between a voltage received from the switching transistor T2 and a first power voltage ELVDD supplied to the driving voltage line PL.

The driving transistor T1 is connected to the driving voltage line PL and the storage capacitor Cst, and may control a driving current flowing from the driving voltage line PL to the display element DPE according to a voltage value stored in the storage capacitor Cst. The display element DPE may emit light having a set or certain luminance according to the driving current. An opposite electrode (for example, a cathode) of the display element DPE may receive a second power voltage ELVSS.

FIG. 4 shows that the pixel circuit PC includes two transistors and one storage capacitor, but the pixel circuit PC may include at least three transistors.

A scan driver configured to provide a scan signal to the pixel circuit PC, a data driver configured to provide a data signal, and/or a power wire configured to provide the first power voltage ELVDD and/or the second power voltage ELVSS may be provided in the peripheral region PA. In embodiments, a pad may be provided in the peripheral region PA, and a display circuit board may be electrically connected to the pad.

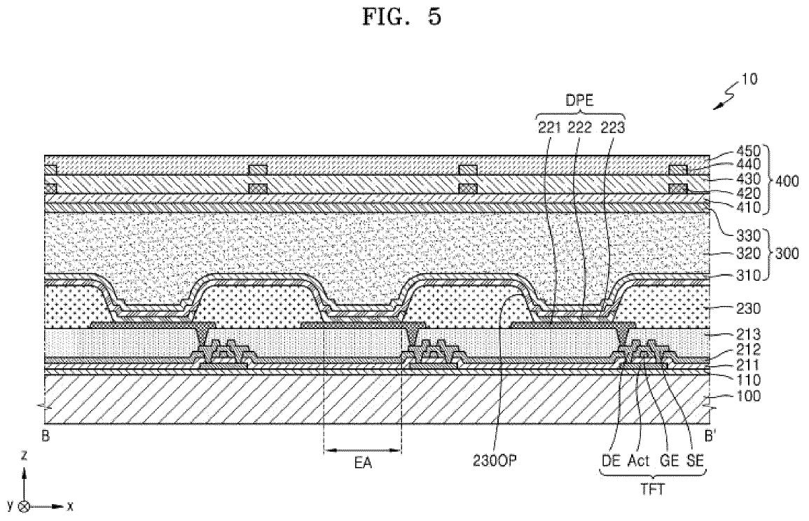

FIG. 5 is a cross-sectional view schematically showing a cross-section of the display panel 10 of FIG. 3 taken along a line B-B′ of FIG. 3. As shown in FIG. 5, the display panel 10 may include the substrate 100, a transistor TFT, the display element DPE, an encapsulation layer 300, and a touch sensor layer 400.

The substrate 100 may include various flexible and/or bendable materials. For example, the substrate 100 may include glass, a metal, and/or polymer resin. In embodiments, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multilayer structure including two layers including polymer resin as described herein and a barrier layer therebetween and including an inorganic material (for example, silicon oxide (SiO_{X}), silicon nitride (SiN_{X}), and/or silicon oxynitride (SiO_{X}N_{Y})), and various suitable modifications may be made.

The display element DPE and the transistor TFT electrically connected to the display element DPE may be over the substrate 100. One display element DPE may correspond to one pixel. For example, the display element DPE may be an organic light-emitting diode.

In more detail, a plurality of transistors TFT may be over the substrate 100. Each of the plurality of transistors TFT may be electrically connected to each of a plurality of display elements DPE. A transistor TFT electrically connected to each of the plurality of display elements DPE may be one transistor included in one pixel circuit PC as described above with reference to FIGS. 3-4.

A buffer layer 110 including an inorganic material, such as silicon oxide (SiO_{X}), silicon nitride (SiN_{X}), and/or silicon oxynitride (SiO_{X}N_{Y}), may be between the transistor TFT and the substrate 100. The buffer layer 110 may serve to increase the smoothness of a top surface of the substrate 100 or to prevent, reduce, or minimize infiltration of impurities from the substrate 100 and/or the like into a semiconductor layer Act of the transistor TFT.

As shown in FIG. 5, the transistor TFT may include the semiconductor layer Act, a gate electrode GE, a source electrode SE, and a drain electrode DE. FIG. 5 shows a top-gate type (or kind) in which the gate electrode GE is on the semiconductor layer Act with a gate insulating layer 211 therebetween, but the disclosure is not limited thereto. For example, the transistor TFT may be a bottom-gate type (or kind).

The semiconductor layer Act may be on the buffer layer 110. The semiconductor layer Act may include a channel region, and a source region and a drain region, doped with impurities, respectively at both sides (e.g., two opposing sides) of the channel region. In embodiments, the impurities may include N-type impurities or P-type impurities. The semiconductor layer Act may include amorphous silicon or polysilicon. In an embodiment, the semiconductor layer Act may include an oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), or zinc (Zn). In embodiments, the semiconductor layer Act may include, as a Zn-oxide-based material, Zn oxide, In—Zn oxide, Ga—In—Zn oxide, and/or the like. In embodiments, the semiconductor layer Act may be an In—Ga—Zn—O (IGZO), In—Sn—Zn—O (ITZO), and/or In—Ga—Sn—Zn—O (IGTZO) semiconductor containing a metal such as indium (In), gallium (Ga), and/or stannum (Sn).

The gate electrode GE may be on the semiconductor layer Act to at least partially overlap the semiconductor layer Act. In more detail, the gate electrode GE may overlap the channel region of the semiconductor layer Act. The gate electrode GE may include various suitable conductive materials (e.g., electrically conductive materials) including molybdenum (Mo), aluminum (Al), copper (Cu), titanium (Ti), and/or the like, and may have various suitable layer structures. For example, the gate electrode GE may include a Mo layer and an Al layer, or may have a multilayer structure of Mo layer/Al layer/Mo layer. In embodiments, the gate electrode GE may have a multilayer structure including an ITO layer covering a metal material.

The gate insulating layer 211 between the semiconductor layer Act and the gate electrode GE may include an inorganic insulating material, such as silicon oxide, silicon nitride, silicon oxynitride, aluminum oxide, titanium oxide, tantalum oxide, hafnium oxide, and/or the like. The gate insulating layer 211 may be a single layer or a multilayer, including the aforementioned materials.

The source electrode SE and the drain electrode DE may be connected to the source region and the drain region of the semiconductor layer Act via a contact hole. The source electrode SE and the drain electrode DE include various suitable conductive materials (e.g., electrically conductive materials) including molybdenum (Mo), aluminum (Al), copper (Cu), titanium (Ti), and/or the like, and may have various suitable layer structures. For example, the source electrode SE and the drain electrode DE may include a Ti layer and an Al layer, or may have a multilayer structure of Ti layer/Al layer/Ti layer. In embodiments, the source electrode SE and the drain electrode DE may have a multilayer structure including an ITO layer covering a metal material.

An interlayer insulating layer 212 may include an inorganic insulating material, such as silicon oxide, silicon nitride, silicon oxynitride, aluminum oxide, titanium oxide, tantalum oxide, hafnium oxide, and/or the like. In embodiments, the interlayer insulating layer 212 may be a single layer or a multilayer, including the aforementioned materials.

As such, the gate insulating layer 211 and the interlayer insulating layer 212, including the inorganic material, may be formed by chemical vapor deposition (CVD) or atomic layer deposition (ALD), but the disclosure is not limited thereto.

The transistor TFT may be covered with an organic insulating layer 213. For example, the organic insulating layer 213 may cover the source electrode SE and the drain electrode DE. The organic insulating layer 213 is a planarization insulating layer, and may include a top surface that is approximately flat. The organic insulating layer 213 may include an organic insulating material, such as a general purpose polymer, such as polymethylmethacrylate (PMMA) and/or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and/or a blend thereof. In an embodiment, the organic insulating layer 213 may include polyimide.

The display element DPE may be on the organic insulating layer 213. The display element DPE may emit red light, green light, or blue light. The display element DPE may be an organic light-emitting diode having, for example, a pixel electrode 221, an opposite electrode 223, and an intermediate layer 222 therebetween and including an emission layer.

As shown in FIG. 5, the pixel electrode 221 is electrically connected to the transistor TFT by contacting either the source electrode SE or the drain electrode DE via a contact hole in the organic insulating layer 213. The pixel electrode 221 includes a transmissive conductive layer including a transmissive conductive oxide, such as ITO, In₂O₃, and/or IZO, and a reflective layer including a metal, such as Al and/or Ag. For example, the pixel electrode 221 may have a three-layer structure of ITO/Ag/ITO.

A pixel-defining layer 230 may be above the organic insulating layer 213. The pixel-defining layer 230 may serve to define a pixel by having an opening 2300P corresponding to each of the pixels, for example, the opening 2300P through which at least a central portion of the pixel electrode 221 is exposed. In embodiments, at least a portion of the intermediate layer 222 may be provided in the opening 2300P, and an emission region EA of the display element DPE may be defined by the opening 2300P. In the embodiment shown in FIG. 5, the pixel-defining layer 230 may serve to prevent or reduce occurrence of arcs, and/or the like at an edge of the pixel electrode 221 by increasing a distance between an edge of the pixel electrode 221 and the opposite electrode 223 above the pixel electrode 221. The pixel-defining layer 230 may include an organic material, such as polyimide and/or hexamethyldisiloxane (HMDSO).

The intermediate layer 222 may include a low-molecular-weight material and/or a polymer material. When the intermediate layer 222 includes the low-molecular-weight material, the intermediate layer 222 may have a structure in which a hole injection layer (HIL), a hole transport layer (HTL), an emission layer (EML), an electron transport layer (ETL), an electron injection layer (EIL), and/or the like are stacked in a single or complex structure, and may be formed by vacuum deposition. When the intermediate layer 222 includes the polymer material, the intermediate layer 222 may have a structure including an HTL and an EML. In embodiments, the HTL may include PEDOT, and the EML may include a polymer material, such as polyphenylene vinylene (PPV) and/or polyfluorene. The intermediate layer 222 may be formed by screen printing, inkjet printing, laser induced thermal imaging (LITI), and/or the like. The intermediate layer 222 is not necessarily limited thereto and may have various suitable structures. In embodiments, the intermediate layer 222 may include a layer that is integrally formed on a plurality of pixel electrodes 221, or may include a layer that is patterned to correspond to each of the plurality of pixel electrodes 221.

The opposite electrode 223 may be on the intermediate layer 222. The opposite electrode 223 may be integrally formed in the plurality of display elements DPE to correspond to the plurality of pixel electrodes 221. Accordingly, the opposite electrode 223 may be commonly provided in the plurality of display elements DPE. The opposite electrode 223 may include a transmissive conductive layer including ITO, In₂O₃, and/or IZO, and may include a semipermeable layer including a metal, such as Al, Mg, and/or Ag. For example, the opposite electrode 223 may be a semipermeable layer including Al, Mg, and/or Ag.

The encapsulation layer 300 may be above the display element DPE. For example, the encapsulation layer 300 may be on the opposite electrode 223. The display element DPE may be easily damaged by moisture, oxygen, and/or the like from the outside, and thus, the encapsulation layer 300 may cover and protect the display element DPE.

The encapsulation layer 300 may include at least one inorganic encapsulation layer and at least one organic encapsulation layer. In an embodiment, as shown in FIG. 5, the encapsulation layer 300 may include a first inorganic encapsulation layer 310, an organic encapsulation layer 320, and a second inorganic encapsulation layer 330, which are sequentially stacked.

The first inorganic encapsulation layer 310 covers the opposite electrode 223 and may include silicon oxide (SiO_{X}), silicon nitride (SiN_{X}), and/or silicon oxynitride (SiO_{X}N_{Y}). As necessary or desired, other layers, such as a capping layer, may be between the first inorganic encapsulation layer 310 and the opposite electrode 223. The first inorganic encapsulation layer 310 may be provided along a structure below the first inorganic encapsulation layer 310, and thus, a top surface of the first inorganic encapsulation layer 310 is not flat as shown in FIG. 5. The organic encapsulation layer 320 covers the first inorganic encapsulation layer 310, and unlike the first inorganic encapsulation layer 310, a top surface of the organic encapsulation layer 320 may be substantially flat. In more detail, the organic encapsulation layer 320 may have a substantially flat top surface in a portion corresponding to the display region DA. The organic encapsulation layer 320 may include at least one material selected from the group consisting of polyethylene terephthalate, polyethylene naphthalate, polycarbonate, polyimide, polyethylene sulfonate, polyoxymethylene, polyarylate, and HMDSO. The second inorganic encapsulation layer 330 covers the organic encapsulation layer 320 and may include silicon oxide (SiO_{X}), silicon nitride (SiN_{X}), and/or silicon oxynitride (SiO_{X}N_{Y}). The second inorganic encapsulation layer 330 may prevent or reduce exposure of the organic encapsulation layer 320 to the outside, by contacting the first inorganic encapsulation layer 310 at an edge outside the display region DA.

In embodiments where the encapsulation layer 300 includes the first inorganic encapsulation layer 310, the organic encapsulation layer 320, and the second inorganic encapsulation layer 330, even when cracks occur in the encapsulation layer 300, it is possible to prevent or reduce connection of such cracks between the first inorganic encapsulation layer 310 and the organic encapsulation layer 320 or between the organic encapsulation layer 320 and the second inorganic encapsulation layer 330. Accordingly, it is possible to prevent, reduce, or minimize formation of a path through which moisture, oxygen, and/or the like from the outside penetrates into the display region DA.

The touch sensor layer 400 may be on the encapsulation layer 300. In more detail, the touch sensor layer 400 may be on the second inorganic encapsulation layer 330. The touch sensor layer 400 may obtain coordinate information according to a touch event of an external input, for example, a finger, and/or an object such as a stylus pen.

The touch sensor layer 400 may include a plurality of touch conductive patterns and a plurality of touch insulating layers. For example, the touch sensor layer 400 may include a first touch insulating layer 410, a first touch conductive pattern 420, a second touch insulating layer 430, a second touch conductive pattern 440, and a third touch insulating layer 450. In an embodiment, the first touch insulating layer 410 may be formed as a single layer or a multilayer, including an inorganic material, such as silicon nitride (SiN_{X}), silicon oxide (SiO_{X}), and/or silicon oxynitride (SiO_{X}N_{Y}). In some embodiments, the first touch insulating layer 410 may include an organic material. In some embodiments, the first touch insulating layer 410 may be omitted.

The first touch conductive pattern 420 may be on the first touch insulating layer 410 and/or the second inorganic encapsulation layer 330. In an embodiment, the first touch conductive pattern 420 may overlap the pixel-defining layer 230. The first touch conductive pattern 420 may not overlap openings in the pixel-defining layer 230. The first touch conductive pattern 420 may include a conductive material (e.g., an electrically conductive material). For example, the first touch conductive pattern 420 may include molybdenum (Mo), aluminum (Al), copper (Cu), titanium (Ti), and/or the like, and may be formed as a multilayer or a single layer, including the aforementioned materials. In an embodiment, the first touch conductive pattern 420 may have a structure (Ti/AI/Ti) in which a titanium layer, an aluminum layer, and a titanium layer are sequentially stacked.

The second touch insulating layer 430 may cover the first touch conductive pattern 420. The second touch insulating layer 430 may be formed as a single layer or a multilayer, including an inorganic material, such as silicon nitride (SiN_{X}), silicon oxide (SiO_{X}), and/or silicon oxynitride (SiO_{X}N_{Y}). In some embodiments, the second touch insulating layer 430 may include an organic material.

The second touch conductive pattern 440 may be on the second touch insulating layer 430. In an embodiment, the second touch conductive pattern 440 may overlap the pixel-defining layer 230. The second touch conductive pattern 440 may not overlap openings in the pixel-defining layer 230. In an embodiment, the second touch conductive pattern 440 may be connected to the first touch conductive pattern 420 via a contact hole provided in the second touch insulating layer 430. The second touch conductive pattern 440 may include a conductive material (e.g., an electrically conductive material). For example, the second touch conductive pattern 440 may include molybdenum (Mo), aluminum (Al), copper (Cu), titanium (Ti), and/or the like, and may be formed as a multilayer or a single layer, including the aforementioned materials. In an embodiment, the second touch conductive pattern 440 may have a structure (Ti/AI/Ti) in which a titanium layer, an aluminum layer, and a titanium layer are sequentially stacked.

The first touch conductive pattern 420 and the second touch conductive pattern 440 may include a plurality of touch sensing electrodes for detecting touch inputs. In an embodiment, the plurality of touch sensing electrodes may detect inputs by using a mutual capacitance method. In another embodiment, the plurality of touch sensing electrodes may detect inputs by using a self capacitance method.

The third touch insulating layer 450 may cover the second touch conductive pattern 440. In an embodiment, the third touch insulating layer 450 may be formed as a single layer or a multilayer, including an inorganic material, such as silicon nitride (SiN_{X}), silicon oxide (SiO_{X}), and/or silicon oxynitride (SiO_{X}N_{Y}). In some embodiments, the third touch insulating layer 450 may include an organic material.

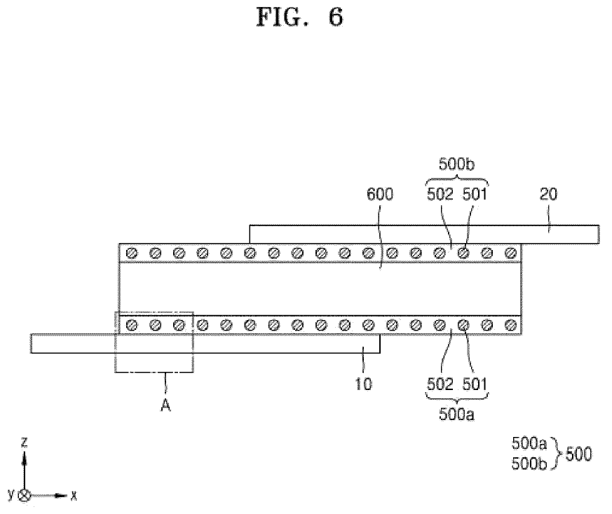

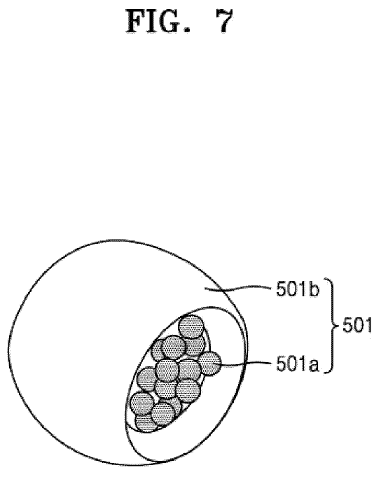

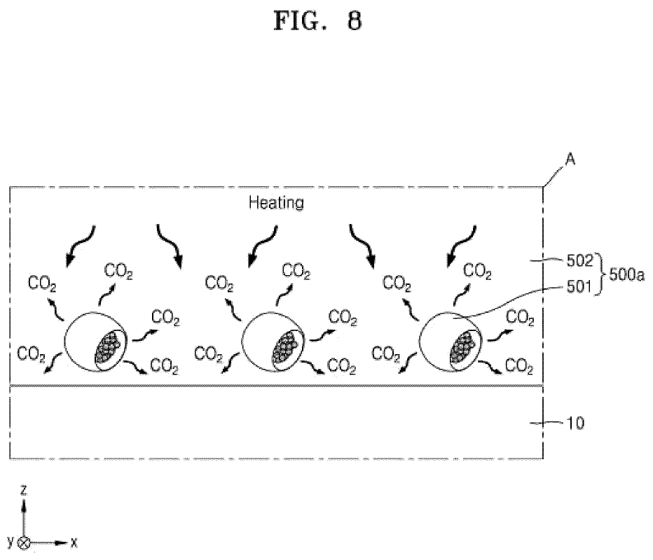

FIG. 6 is a schematic cross-sectional view of a display panel according to an embodiment and a member that are bonded to each other via an OCA and an auxiliary layer. FIG. 7 is a schematic perspective view of a nanocapsule included in an auxiliary layer. FIG. 8 is an enlarged schematic view of a region A of a cross-section of the display apparatus shown in FIG. 6. In more detail, FIG. 8 is a cross-sectional view schematically showing that gas is generated from cores of nanocapsules due to heat.

Referring to FIG. 6, a first auxiliary layer 500a may be provided. The first auxiliary layer 500a may be in contact with an interface of the display panel 10. The first auxiliary layer 500a may include an OCA composition 502 and a nanocapsule 501. An OCA 600 may be on the first auxiliary layer 500a. In embodiments, the first auxiliary layer 500a may be between the display panel 10 and the OCA 600. A second auxiliary layer 500b may be further on the OCA 600. A member 20 may be on the second auxiliary layer 500b. The second auxiliary layer 500b may be in contact with an interface of the member 20. The display panel 10 and the member 20 may be connected to each other via the OCA 600 and the first and second auxiliary layers 500a and 500b. The first and second auxiliary layers 500a and 500b may be respectively in contact with the interface of the display panel 10 and the interface of the member 20, with the OCA 600 therebetween. The member 20 may be at least one of the cover window CW (see FIG. 2), the functional layer FL (see FIG. 2), or the antenna film AF (see FIG. 2). However, the disclosure is not limited thereto.

The OCA composition 502 included in the first auxiliary layer 500a and the second auxiliary layer 500b may include at least one of 2-ethylhexyl acrylate, butyl acrylate, vinyl acetate, methyl methacrylate, ethyl acrylate, methyl acrylate, benzyl acrylate, phenoxyethyl acrylate, acrylic acid, hydroxyethyl methacrylate, glycidyl methacrylate, acetoacetoxyethyl methacrylate, 2-hydroxyethyl acrylate, or isobornyl acrylate.

Referring to FIGS. 7-8, the nanocapsule 501 may include a core 501a and a shell 501b surrounding the core 501a. The core 501a of the nanocapsule 501 may include an inorganic material that generates gas by way of thermal decomposition at a temperature of at least about 50° C. and not more than about 100° C. In more detail, the core 501a of the nanocapsule 501 may include sodium bicarbonate (NaHCO₃). Sodium bicarbonate (NaHCO₃) included in the core 501a of the nanocapsule 501 may be thermally decomposed at a temperature of at least about 50° C. and not more than about 100° C. to produce carbon dioxide (CO₂). The core 501a of the nanocapsule 501 generates carbon dioxide (CO₂) at a temperature of at least about 50° C. and not more than about 100° C., and thus, the OCA 600 and the first and second auxiliary layers 500a and 500b may be efficiently debonded from the display panel 10 and the member without damaging the display panel 10.

In an embodiment, the core 501a of the nanocapsule 501 may include not only sodium bicarbonate (NaHCO₃) but also at least one of zinc hydroxide (Zn(OH)₂), ammonium bicarbonate (NH₄HCO₃), aluminum hydroxide (Al(OH)₃), calcium carbonate (CaCO₃), hydrogen sulfide (H₂S), sulfur dioxide (SO₂), nitric oxide (NO), nitrous oxide (N₂O), or arsenic trioxide (As₂O₃).

The shell 501b of the nanocapsule 501 may include an acrylic monomer. In more detail, the shell 501b of the nanocapsule 501 may include polyacrylonitrile (PAN) and PMMA. In embodiments, the shell 501b of the nanocapsule 501 may include at least one of methyl methacrylate, acrylonitrile, 2-ethylhexyl acrylate, N-butyl acrylate, vinyl acetate, ethyl acrylate, methyl acrylate, benzyl acrylate, phenoxyethyl acrylate, acrylic acid, hydroxyethyl methacrylate, glycidyl methacrylate, acetoacetoxyethyl methacrylate, 2-hydroxyethyl acrylate, isobornyl acrylate, or octadecyl methacrylate.

In an embodiment, the shell 501b of the nanocapsule 501 includes an acrylic monomer having a similar structure to the OCA composition 502, and thus, in an auxiliary layer 500, the nanocapsule 501 may be efficiently dispersed in the OCA composition 502, and the light transmittance of the auxiliary layer 500 may be ensured or improved.

When the shell 501b of the nanocapsule 501 includes PAN and PMMA, the ratio of PAN and PMMA may be between about 0:10 and about 9:1. The ratio of PAN and PMMA, included in the shell 501b of the nanocapsule 501, should be between about 0:10 and about 9:1 to prevent or reduce coloring of the auxiliary layer 500 (for example, yellowish) and to ensure or improve light transmittance of the display apparatus.

The diameter of the nanocapsule 501 may be at least about 100 nm and not more than about 2 μm. When the diameter of the nanocapsule 501 is less than 100 nm, the debonding strength of the auxiliary layer 500 including the nanocapsule 501, which is a gas-generating particle, may not be ensured, and when the diameter of the nanocapsule 501 is greater than 2 μm, the light transmittance of the display apparatus may not be ensured.

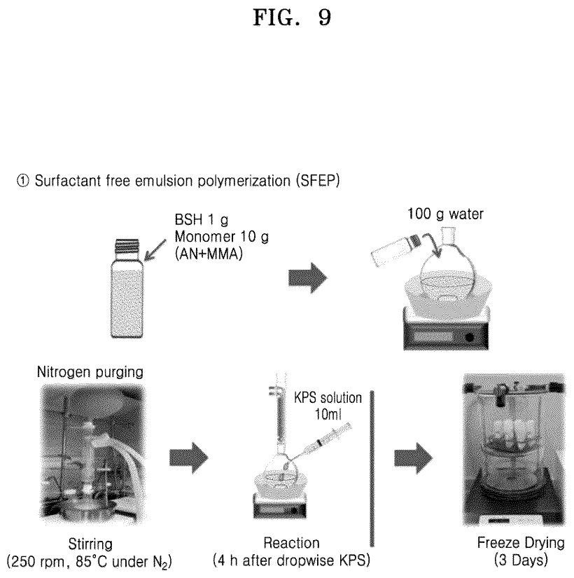

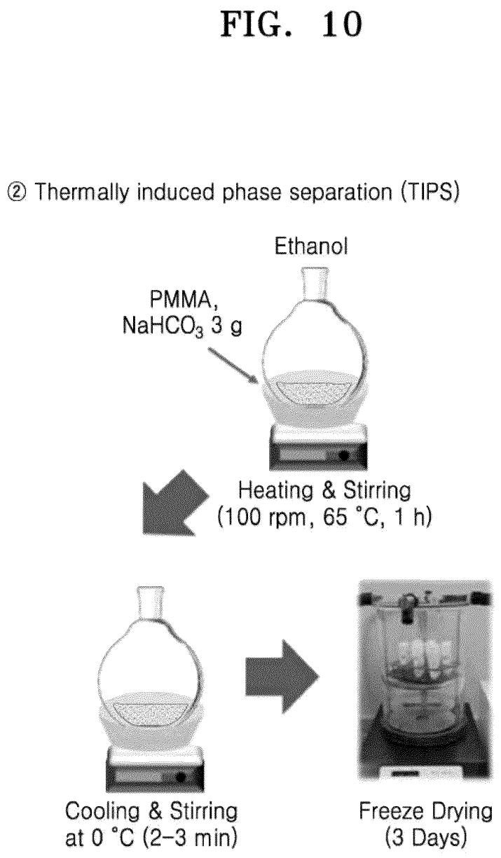

FIGS. 9-10 are schematic flow charts showing embodiments of a method of preparing a material for forming an auxiliary layer.

Referring to FIG. 9, a method of preparing a material for forming an auxiliary layer via surfactant-free emulsion polymerization (SFEP) is schematically shown. As described above, the material for forming the auxiliary layer may include the OCA composition 502 and the nanocapsule 501. First, 7 g of acrylonitrile (AN), 3 g of methyl methacrylate (MMA), and 1 g of sodium bicarbonate (NaHCO₃) are suitably or sufficiently stirred for about 10 minutes to about 20 minutes. After 100 g of deionized water (D.I water) is added to the resultant mixed solution, the temperature is raised to 85° C., and stirring is done at 250 rpm under nitrogen atmosphere. When the temperature reaches 85° C., a potassium persulfate (KPS) aqueous solution (10 wt %), which is an initiator, is slowly added, and the reaction proceeds for four hours. The synthesized solution is centrifuged (6,000 rpm, three times) and washed with D.I water to remove any (or substantially any) unreacted residues. Particles from which unreacted residues have been removed are dried in a freeze dryer for three days.

SFEP is a principle in which polymerization is carried out by radical initiation while potassium persulfate, which is an anionic initiator, acts as an emulsifier, allowing for stable particle formation without a surfactant. This synthesis method allows for easy control of particle size by reaction time, initiator concentration, and/or the like, and may facilitate mass synthesis via a one-pot reaction.

Referring to FIG. 10, a method of preparing a material for forming an auxiliary layer via thermally induced phase separation (TIPS) is schematically shown. First, a solution in which 0.5 g of PMMA and 3 g of sodium bicarbonate (NaHCO₃) are mixed is stirred in 100 g of ethanol at 100 rpm and 65° C. for one hour. The resultant mixed solution is rapidly carried to ice water that has been cooled to 0° C., followed by stirring for two minutes. The prepared solution is centrifuged (6,000 rpm, three times) to remove any (or substantially any) unreacted residues, and then dried in a freeze dryer for three days.

TIPS is a principle of forming particles by inducing uniform mixing of polymer solutions based on temperature changes, allowing for control of particle size by changing process parameters such as synthesis temperature and polymer concentration, and facilitating large-scale synthesis due to a short reaction time and a simplified structure.

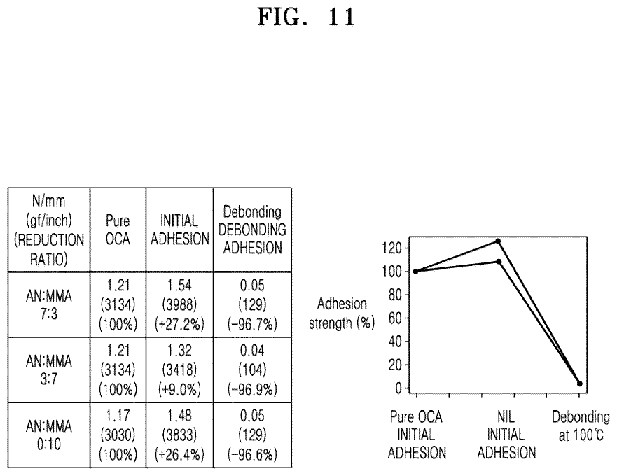

FIG. 11 schematically shows a result of measuring initial adhesions and debonding adhesions of samples of materials for forming an auxiliary layer according to an embodiment. In more detail, FIG. 11 schematically shows a result of measuring initial adhesions and debonding adhesions of samples of the materials for forming the auxiliary layer, in which the shell 501b (see FIG. 7) of the nanocapsule 501 (see FIG. 7) consists of PAN and PMMA in ratios of 7:3, 3:7, and 0:10.

Referring to FIG. 11, when the initial adhesions of the samples of the materials for forming the auxiliary layer, in which the shell 501b of the nanocapsule 501 consists of PAN and PMMA in the ratios of 7:3, 3:7, and 0:10, were compared to a pure OCA, the initial adhesions were respectively increased by 27.2%, 9.0%, and 26.4%. In embodiments, when the debonding adhesions of the samples were compared to the initial adhesions, the debonding adhesions were respectively decreased by 96.7%, 96.9%, and 96.6%.

As a result of measuring the initial adhesions and the debonding adhesions via experiments, the materials for forming the auxiliary layer, which include nanocapsules, according to embodiments exhibited high initial adhesions and correspondingly high debonding adhesions, thereby improving the efficiency of an adhesive and thus improving the reliability and quality of a display apparatus.

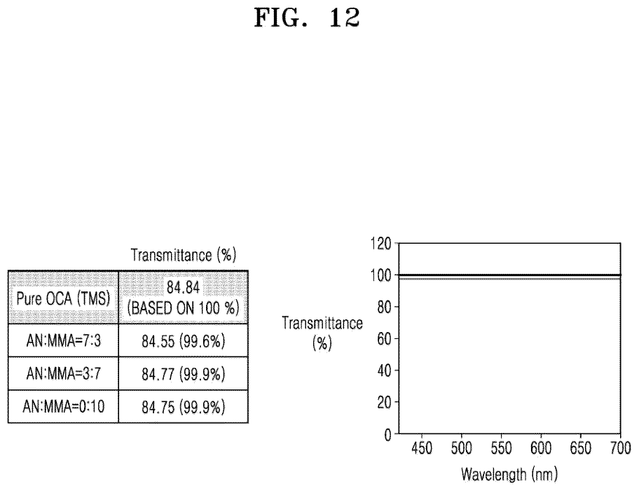

FIG. 12 schematically shows light transmittances of samples of materials for forming an auxiliary layer according to an embodiment. In more detail, FIG. 12 schematically shows light transmittances of samples of materials for forming an auxiliary layer, in which the shell 501b (see FIG. 7) of the nanocapsule 501 (see FIG. 7) consists of PAN and PMMA in ratios of 7:3, 3:7 and 0:10.

Referring to FIG. 12, when the light transmittances of the samples of the materials for forming the auxiliary layer, in which the shell 501b of the nanocapsule 501 consists of PAN and PMMA in the ratios of 7:3, 3:7 and 0:10, were compared to a pure OCA, high light transmittances of 99.6%, 99.9%, and 99.9% were exhibited.

As a result of measuring the light transmittances via experiments, the materials for forming the auxiliary layer, which include the nanocapsule 501, according to embodiments exhibited high light transmittances, thereby ensuring the reliability and quality of a display apparatus.

In an embodiment, the auxiliary layer 500 is on the display panel 10 or the member 20 with the OCA therebetween so as to be in contact with the interface of the display panel 10 or the interface of the member 20, and includes the nanocapsule 501, which is a gas-generating particle and has a diameter of at least about 100 nm and not more than about 2 μm, to improve debonding strength and simultaneously ensure light transmittance, thereby improving the reliability and quality of a display apparatus.

According to an embodiment, it is possible to embody a display apparatus having improved reliability and improved quality. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims and equivalents thereof.

What is claimed is:

1. A display apparatus comprising:
a display panel;
an optically clear adhesive (OCA) over the display panel; and
an auxiliary layer between the display panel and the OCA and comprising a nanocapsule and an OCA composition,
wherein the nanocapsule is a gas-generating particle and has a diameter of at least about 100 nm and not more than about 2 μm.

2. The display apparatus of claim 1, wherein the auxiliary layer is in contact with an interface of the display panel.

3. The display apparatus of claim 1, wherein a core of the nanocapsule comprises an inorganic material.

4. The display apparatus of claim 3, wherein the core of the nanocapsule comprises an inorganic material that generates gas by thermal decomposition at a temperature of at least about 50° C. and not more than about 100° C.

5. The display apparatus of claim 4, wherein the core of the nanocapsule comprises sodium bicarbonate (NaHCO₃).

6. The display apparatus of claim 1, wherein the core of the nanocapsule comprises at least one of zinc hydroxide (Zn(OH)₂), ammonium bicarbonate (NH₄HCO₃), aluminum hydroxide (Al(OH)₃), calcium carbonate (CaCO₃), hydrogen sulfide (H₂S), sulfur dioxide (SO₂), nitric oxide (NO), nitrous oxide (N₂O), or arsenic trioxide (As₂O₃).

7. The display apparatus of claim 1, wherein a shell of the nanocapsule comprises an acrylic monomer.

8. The display apparatus of claim 7, wherein the shell of the nanocapsule comprises polyacrylonitrile (PAN) and polymethyl methacrylate (PMMA).

9. The display apparatus of claim 8, wherein a ratio of PAN and PMMA, included in the shell of the nanocapsule is between about 0:10 and about 9:1.

10. The display apparatus of claim 7, wherein the shell of the nanocapsule comprises at least one of methyl methacrylate, acrylonitrile, 2-ethylhexyl acrylate, N-butyl acrylate, vinyl acetate, ethyl acrylate, methyl acrylate, benzyl acrylate, phenoxyethyl acrylate, acrylic acid, hydroxyethyl methacrylate, glycidyl methacrylate, acetoacetoxyethyl methacrylate, 2-hydroxyethyl acrylate, isobornyl acrylate, or octadecyl methacrylate.

11. The display apparatus of claim 1, wherein the OCA composition comprises at least one of 2-ethylhexyl acrylate, N-butyl acrylate, vinyl acetate, methyl methacrylate, ethyl acrylate, methyl acrylate, benzyl acrylate, phenoxyethyl acrylate, acrylic acid, hydroxyethyl methacrylate, glycidyl methacrylate, acetoacetoxyethyl methacrylate, 2-hydroxyethyl acrylate, or isobornyl acrylate.

12. A display apparatus comprising:
a display panel;
an optically clear adhesive (OCA) on the display panel;
an auxiliary layer on the OCA and comprising a nanocapsule and an OCA composition; and
a member on the auxiliary layer,
wherein the nanocapsule is a gas-generating particle and has a diameter of at least about 100 nm and not more than about 2 μm.

13. The display apparatus of claim 12, wherein the auxiliary layer is in contact with an interface of the member.

14. The display apparatus of claim 12, wherein a core of the nanocapsule comprises an inorganic material.

15. The display apparatus of claim 14, wherein the core of the nanocapsule comprises an inorganic material that generates gas by thermal decomposition at a temperature of at least about 50° C. and not more than about 100° C.

16. The display apparatus of claim 15, wherein the core of the nanocapsule comprises sodium bicarbonate (NaHCO₃).

17. The display apparatus of claim 12, wherein the core of the nanocapsule comprises at least one of zinc hydroxide (Zn(OH)₂), ammonium bicarbonate (NH₄HCO₃), aluminum hydroxide (Al(OH)₃), calcium carbonate (CaCO₃), hydrogen sulfide (H₂S), sulfur dioxide (SO₂), nitric oxide (NO), nitrous oxide (N₂O), or arsenic trioxide (As₂O₃).

18. The display apparatus of claim 12, wherein a shell of the nanocapsule comprises an acrylic monomer.

19. The display apparatus of claim 18, wherein the shell of the nanocapsule comprises polyacrylonitrile (PAN) and polymethyl methacrylate (PMMA).

20. The display apparatus of claim 19, wherein a ratio of PAN and PMMA, included in the shell of the nanocapsule is between about 0:10 and about 9:1.

21. An electronic apparatus comprising:
a display apparatus comprising:
a display panel;
an optically clear adhesive (OCA) over the display panel; and
an auxiliary layer between the display panel and the OCA and comprising a nanocapsule and an OCA composition,
wherein the nanocapsule is a gas-generating particle and has a diameter of at least about 100 nm and not more than about 2 μm.

22. The electronic apparatus of claim 21, wherein the electronic apparatus comprises a mobile phone, a smartphone, a tablet personal computer (PC), a mobile communication terminal, an electronic organizer, an e-book, a portable multimedia player (PMP), a navigation device, an ultra mobile PC (UMPC), a television, a laptop, a monitor, a billboard, an Internet of things (IOT) device, a wearable device, or a vehicle.
